(19) United States
(12) Patent Application Publication
(10) Pub. No.: US 2018/0204974 A1
(43) Pub. Date: Jul. 19, 2018

(54) SOURCE OF COLLIMATED LIGHT, THE METHOD FOR PRODUCING SAME AND USE OF SAME FOR THE EMISSION OF SINGLE PHOTONS

(71) Applicant: Commissariat à l'énergie atomique et aux énergies alternatives, Paris (FR)

(72) Inventors: Salim Boutami, Grenoble (FR); Nicolas Pauc, Grenoble (FR)

(21) Appl. No.: 15/867,215

(22) Filed: Jan. 10, 2018

(30) Foreign Application Priority Data
Jan. 13, 2017 (FR) 17 50299

(51) Int. Cl. H01L 33/06; H01L 33/24; H01L 33/44; H01L 33/10

(52) U.S. Cl. CPC H01L 33/06; H01L 33/24; H01L 2933/0025; H01L 33/10; H01L 33/44

(57) ABSTRACT

A source of collimated light, in particular a source of single photons. The source comprises a cavity in the shape of an inverted pyramid formed in a substrate. At least one quantum dot (Bq) suitable for emitting light with a wavefront is arranged at the apex of the inverted pyramid and a structure (4) having an index gradient fills the cavity. This structure has an effective index that decreases from the centre of the base towards the sides. Thus, the wavefront of the light emitted by the at least one quantum dot is flattened. The invention extends to the method for manufacturing such a source, and to its use for the emission of a sequence of single photons.

### CROSS-REFERENCE TO RELATED APPLICATIONS

This application claims priority from French Patent Application No. 17 50299 filed on Jan. 13, 2017. The content of this application is incorporated herein by reference in its entirety.

### TECHNICAL FIELD

The field of the invention is that of sources of light, and more particularly that of sources of single photons.

### PRIOR ART

Sources of single photons are capable of emitting a single photon at a time. They generally consist of an emitter such as a quantum dot, and the emission of a photon is carried out therein using an injected electron-hole pair.

The interest of these sources is the fundamental study of optical and quantum processes, but also quantum cryptography. Indeed, if it is possible to transmit information in bits each consisting of a single photon, the interception of messages can be protected against or at least detected.

In order for a source of single photons to be usable, it must be possible to efficiently collect the emitted photon. For this, the source must be able to emit the photon in a directional manner.

A well-known source of single photons is described in the article “Quantum dots as single-photon sources for quantum information processing” (D C Unitt et al 2005 J. Opt. B: Quantum Semiclass. Opt. 7 S129). It consists of a pillar etched via reactive-ion etching, with a quantum dot inside it, surrounded by Braggs mirrors. Bragg mirrors allow the formation of a Fabry-Perot cavity that exacerbates the probability of emission of the quantum dot in this resonance mode. However, it is observed that this type of source diverges. Moreover, because of the strong resonance of this source (long lifetime of the photon emitted in the cavity), there is a risk that the photon will be diffracted by the etching-edge roughness of the pillar.

Another type of source of single photons is presented in the article “A highly efficient single-photon source based on a quantum dot in a photonic nanowire” (J Claudon et al., Nature Photonics 4, 174-177 (2010)). This source is in the form of a pillar, the upper tip of which is refined by suitable etching conditions. A mirror is positioned under the pillar in order to reflect the light upwards. This source is not very resonant, which prevents the light from being diffracted by roughness. Moreover, the refining of the top of the pillar into a point allows the mode of the pillar to be enlarged spatially and thus be made less angularly divergent. This source thus has good emission directivity.

However, the positioning of the quantum dot inside a pillar requires precise alignment, which is not easy. Moreover, it is difficult to precisely control the shape given to the tip of the pillar, and thus the collimation of the source cannot be controlled well.

### DISCLOSURE OF THE INVENTION

One goal of the invention is to propose a source of collimated light that does not have these disadvantages. For this purpose, the invention proposes a source of collimated light comprising a pyramidal cavity formed in a substrate having a front face. The pyramidal cavity has an axis of symmetry, a base at the front face of the substrate, a centre of the base, sides and an apex below the centre of the base along the axis of symmetry. At least one quantum dot suitable for emitting light with a wavefront is arranged at the apex of the pyramidal cavity. A structure having an index gradient fills the pyramidal cavity. Its effective index decreases from the centre of the base towards the sides in such a way as to flatten the wavefront of the light emitted by the at least one quantum dot.

Certain preferred but not limiting aspects of this source are the following:
the structure having an index gradient has a continuous variation of the refractive index from the centre of the base towards the sides;
the structure having an index gradient is a stack of levels successively deposited in the pyramidal cavity conformally to the sides, the effective index of each level increasing gradually from one level to another in the succession of the deposited levels;
the levels have the same thickness;
each level comprises a first layer and a second layer made from different materials, the relative thickness of the first and second layers of a level varying gradually from one level to another in the succession of the deposited levels;
in each level, the material of the first layer has a refractive index lower than the refractive index of the material of the second layer, and a factor of filling of a level by the first layer decreases from one level to another in the succession of the deposited levels;
the material of the first layer is silica and the material of the second layer is amorphous silicon;
it comprises a single quantum dot;
the quantum dot is arranged in a dielectric layer sandwiched between two doped semiconductor layers, one n-type, the other p-type;
it further comprises a reflective structure on the sides of the pyramidal cavity, for example a Bragg mirror or a metal layer.

The invention extends to the use of this source for the emission of a sequence of single photons, for example in a quantum-cryptography process. The invention also relates to a method for manufacturing such a source of collimated light.

### BRIEF DESCRIPTION OF THE DRAWINGS

Other aspects, goals, advantages and features of the invention will be better understood upon reading the following detailed description of preferred embodiments of said invention, given as a non-limiting example, and made in reference to the appended drawings in which:

FIGS. 1a-1f, 2a-2h and 3a-3e illustrate three possible embodiments of a method for manufacturing a source according to the invention;

FIGS. 4a, 4b and 4c are diagrams representing the wavefronts emitted, respectively, by a source not having a structure having an index gradient, a source having a structure having an index gradient but not provided with a mirror, and a source having an index gradient and of a mirror;

FIG. 5 is a diagram of a source according to the invention;

FIGS. 6a, 6b and 6c show, respectively, the emission of a source having only one Bragg mirror, of a source having a structure having an index gradient but not provided with a mirror, and of a source having a structure having an index gradient and provided with a Bragg mirror.

### DETAILED DISCLOSURE OF SPECIFIC EMBODIMENTS

The invention relates to a source of collimated light, for example a source intended to emit a sequence of single photons.

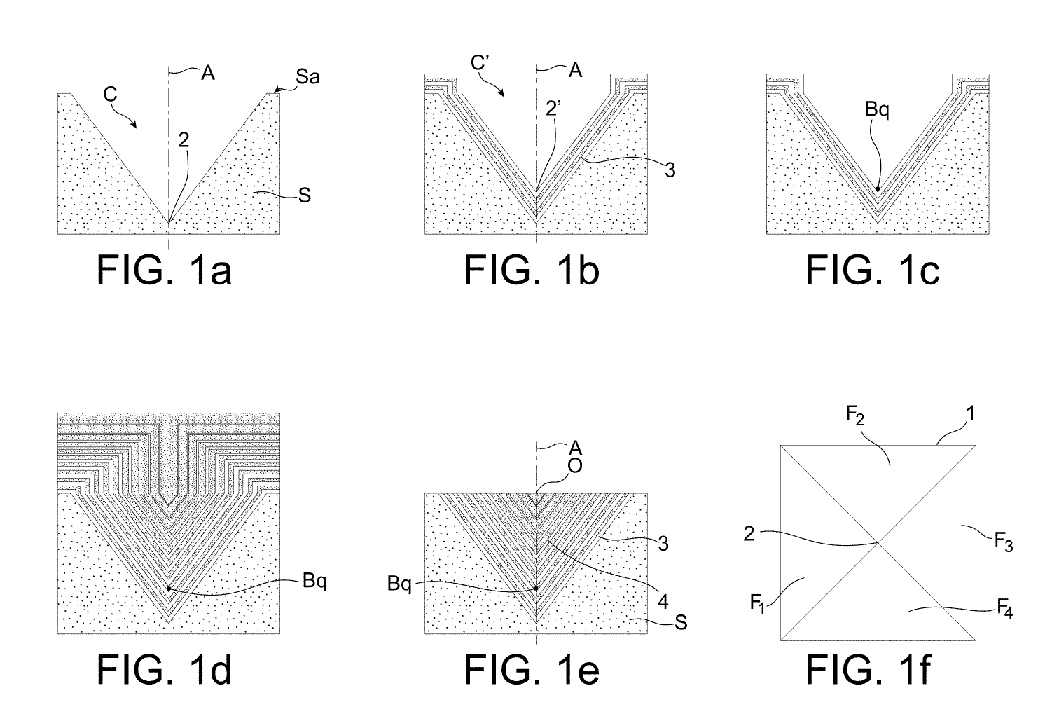

In reference to FIGS. 1a-1f, the source comprises a pyramidal cavity C, C′ formed in a substrate S having a front face Sa. The pyramidal cavity C, C′ has a base at the front face Sa of the substrate, the base comprising a centre O and a contour 1. The pyramidal cavity C, C′ further has an axis of symmetry A passing through the centre C of the base, sides F1-F4 extending from the contour of the base and coming together at an apex 2, 2′ of the cavity located below the centre O of the base along the axis of symmetry A.

FIGS. 1a-1e propose cross-sectional views in a plane perpendicular to the front face of the substrate passing through a diagonal of the base of the pyramidal cavity. FIG. 1f is a top view of the cavity on which the sides F1-F4 (face of the pyramid) can be seen.

In an embodiment shown in FIG. 1a, the cavity C is directly produced via etching of the substrate. In an alternative embodiment shown in FIG. 1b, the sides of the cavity C directly produced via etching of the substrate are coated with a reflective structure 3, thus forming a cavity C′ having an apex 2′, the sides of which are formed by the reflective structure.

The source also comprises at least one quantum dot Bq suitable for emitting light with a wavefront. The at least one quantum dot is arranged at the apex 2, 2′ of the pyramidal cavity C, C′. In order to emit single photons, a single quantum dot is provided.

A structure 4 having an index gradient fills the pyramidal cavity. The effective index of this structure decreases from the centre C towards the sides F1-F4. Thus, the wavefront of the light emitted by the at least one quantum dot Bq is flattened, thus collimating the light emitted by the at least one quantum dot. Effective index designates the average index seen by the light. This effective index can be different from the local refractive index, this local index corresponding for example to the index of the material(s) forming the levels of a stack formed in the pyramidal cavity as described below.

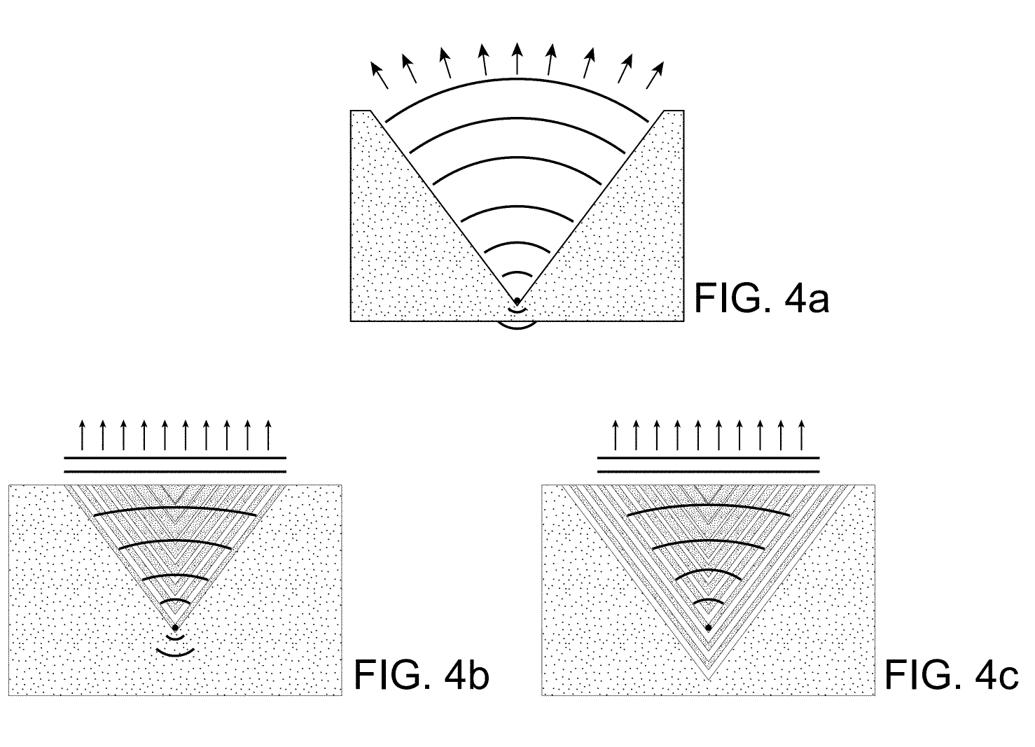

FIG. 4a shows the wavefront emitted by a quantum dot arranged at the apex of a pyramidal cavity not having a structure having an index gradient. This wavefront is spherical, divergent. A photon thus emitted can therefore go in any direction, and it can thus be difficult to collect.

FIG. 4b shows the wavefront emitted by a quantum dot arranged at the apex of a pyramidal cavity filled with a structure having an index gradient according to the invention. The structure having an index gradient flattens the wavefront, which allows the light emitted to be collimated. This results in easier collection of the photon thus emitted.

In FIG. 4b, light leaves the apex of the pyramid in the direction of the substrate. In order to prevent this, there can be a reflective structure on the sides of the pyramidal cavity. Thus, as shown in FIG. 4c, all the light is emitted upwards while being collimated.

It is noted here that a single photon cannot simultaneously go upwards and downwards. Thus, when a simulation shows a portion of the light going upwards, and a portion downwards, this means that a single photon has a certain probability of going upwards, and a complementary probability of going downwards, these probabilities being prorated according to the quantities of light given per simulation. With the reflective structure, it is imposed that all the photons go upwards with a probability of 1.

The formation of the pyramidal cavity typically involves etching of the substrate, for example anisotropic wet etching. The solution for anisotropic wet etching is generally KOH (potassium hydroxide) or TMAH (tetramethylammonium hydroxide). The etching kinetics are dependent on the crystalline planes, which leads to the inverted-pyramid shape. A mask of resin is first made on the front face of the substrate, the mask having small openings made via photolithographies that allow the etching to be localised and initiated. More particularly, a substrate of Si provided with an SiO₂ or Si₃N₄ surface layer can be used. The surface layer is covered with a mask of resin defined by lithography and a hard mask is defined via wet or dry etching of the surface layer through the mask of resin. Then, the resin is removed and the etching of the pyramid is carried out. At the end of this etching, the hard mask can be removed via dry or wet etching.

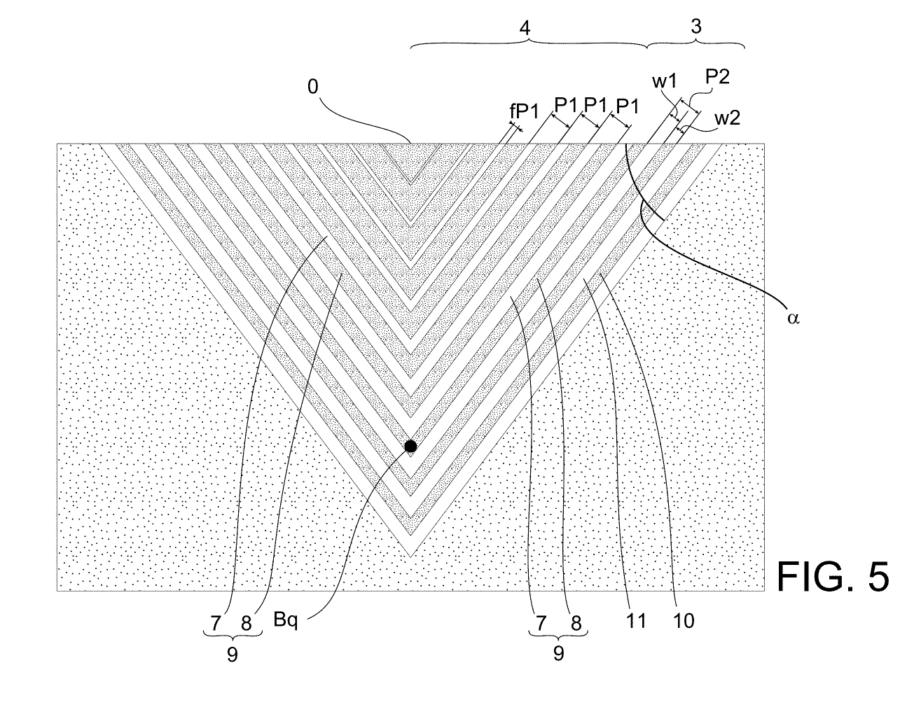

The substrate is for example a substrate of silicon. Its anisotropic chemical etching leads to the formation of an inverted pyramid, with a characteristic angle of 54.7° between a side of the cavity and the horizontal plane corresponding to the front face of the substrate. This angle is designated by a in FIG. 5.

The substrate can also be made from a III-V material, for example from InP or InGaAs that can also be etched in a wet anisotropic way.

The base of the pyramidal cavity can have various shapes, in particular according to the nature of the crystal. It can in particular be square or hexagonal. It must have a dimension greater than the wavelength emitted in order to prevent phenomena of diffraction.

The arrangement of the at least one quantum dot at the apex of the pyramidal cavity can involve the deposition of a colloidal solution of quantum dots on the substrate. Via capillarity, these quantum dots place themselves at the bottom of the pyramidal cavities. Self-alignment is thus achieved.

The control of the concentration of quantum dots in the colloidal solution allows the number of cavities provided with a single quantum dot to be controlled. A concentration of one quantum dot per volume of a pyramidal cavity is thus preferably chosen. The fact that there is only one quantum dot in a cavity can be verified by carrying out the photoluminescence of the bottom of the pyramid and by verifying that the optical signal emitted corresponds to the spectral signature of a single emitter (observation of rays of excitonic or even multiexcitonic origin, as well as the observation of the antibunching of photons on the emission ray implying the emission of a single photon at a given time).

In an alternative embodiment, a resin for electron-beam lithography is manufactured, said resin being enriched with colloidal quantum dots. The sample is coated with this resin, also including at the bottom of the pyramids. Electron-beam lithography allows a block of resin to be left at the bottom of the pyramid containing a colloidal quantum dot. An oxygen plasma allows the resin to be removed in order to only leave the quantum dot.

When the substrate is made of a III-V material, because of the compatibility of the materials, the growth of quantum dots can be carried out directly from the apex of the cavities.

The structure having an index gradient that fills the cavity can have a continuous variation in refractive index. For this, the composition of an alloy (for example SiGe deposited via epitaxy) or the composition of a mixture of materials (for example Nb₂O₅/SiO₂, SiN/SiO₂ or TiO₂/SiO₂) can be continuously modified during the formation of the structure having an index gradient in the cavity via deposition of such an alloy or of such a mixture in the cavity conformally to the sides.

In an alternative embodiment, the filling of a pyramidal cavity by a structure having an index gradient, the effective index of which decreases from the centre of the base towards the sides of the cavity, can involve the formation of a stack of levels in the cavity, the levels being successively deposited in the pyramidal cavity conformally to the sides.

The effective index of each level increases gradually from one level to another in the succession of the deposited levels. Thus, at the base, the effective index is lower at the contour (1^{st} level deposited) than at the centre (last level deposited). A pseudo index gradient is created in this way (the variation in index is of a discrete nature that approximates a continuous variation).

The levels preferably have the same thickness, noted as P1 in FIG. 5. This thickness is advantageously sufficiently small for the pseudo index gradient to allow a true index gradient to be approximated, or less than λ/2 (with λ being the emission wavelength).

In one embodiment, the levels are deposits of an alloy or of a mixture of materials, the composition of which differs from one level to another.

In another embodiment shown in particular in FIG. 5, the levels 9 are bilayers. Each bilayer has a first layer 7 and a second layer 8 made from different materials. The relative thickness of the first and second layers of a level varies gradually from one level to another in the succession of the deposited levels.

In each bilayer, the material of the first layer has a refractive index lower than the refractive index of the material of the second layer. A factor of filling of a level by the first layer decreases from one level to another in the succession of the deposited levels.

The material of the first layer 7 can be silica (index n_{SiO2}=1.5), the material of the second layer 8 being amorphous silicon (index n_{Si}=3.5). Considering this example of an embodiment, f is the local concentration of silica that is a function of the distance x from the centre of the base of the pyramidal cavity along a diagonal of the base of the pyramidal cavity. The effective index is expressed as:

\hat{n}(x)={square root over (f(x)·n_{SiO2}²+(1−f(x))·n_{Si}²)} (1)

In order to carry out the collimation, the variation in local index must approximately verify the following relationship in order to compensate for the difference in distance travelled by the light from the apex of the pyramid between the centre of the base and a point on the base located at a distance x from the centre.

$$\hat{n} ( x ) = \hat{n} ( 0 ) \cdot \frac{tan α \cdot X}{\sqrt{{x}^{2} + {tan}^{2} α \cdot {X}^{2}}} \qquad ( 2 )$$

where X designates the length of a half-diagonal of the base of the pyramid (x=X designating the intersection of the diagonal and the contour of the base), and where a corresponds to the etching angle.

In particular,

\hat{n}(X)=\hat{n}(0)·sin α (3)

With an etching angle of α=54.7° for the silicon, the following indices, for example, can be adopted: \hat{n}(0)=3 and \hat{n}(X)=2.5.

The filling factor of the silica changes according to the previous equations according to

$$f ( x ) = \frac{{n}_{Si}^{2} - ( {\hat{n} ( 0 )}^{2} * \frac{{tan}^{2} α \cdot {X}^{2}}{{x}^{2} + {tan}^{2} α \cdot {X}^{2}} )}{{n}_{Si}^{2} - {n}_{SiO 2}^{2}} .$$

In FIG. 5, the thickness of the layer of silica of a bilayer is noted as f.P1, the thickness of the layer of silicon being (1−f).P1 in order for the bilayer to have the thickness P1.

It is noted above that the sides of the cavity can be coated with a reflective structure 3. Such a structure is formed after the etching of the pyramidal cavity and before the arrangement of the at least one quantum dot in the latter. In the above formulas, if such a reflective structure is present, X corresponds to the border between the structured 4 having an index gradient and the reflective structure 3.

In reference for example to FIG. 5, the reflective structure 3 is for example a Bragg mirror deposited on the sides of the cavity after the etching of the substrate. Such a Bragg mirror is an alternation of layers having different optical indices, for example layers of silica and of silicon. These are quarter-wave layers, or odd multiples of quarter-waves. Preferably, quarter-wave layers are chosen that are of interest because they are reflective over a large range of angle of incidence. The Bragg mirror consists for example of a stack of Si/SiO2 bilayers, each bilayer having a thickness P2=λ/4n_{Si}+λ/4n_{SiO2}. In the example of FIG. 5, the Bragg mirror 3 comprises three Si/SiO2 bilayers having a thickness P2, each bilayer comprising a layer of silica 10 having a thickness w1=λ/4n_{SiO2} and a layer of silicon 11 having a thickness w2=λ/4n_{Si}.

One advantage of the pyramid configuration is that the Bragg mirror is not planar, but surrounds the quantum dot. It thus always sees a wavefront more or less at normal incidence, which allows it to be efficient (a Bragg mirror functions less efficiently with a high angle of incidence).

In an alternative embodiment, the reflective structure comprises a metal layer (for example made of aluminium, copper or gold) deposited on the sides of the cavity after the etching of the substrate, and a spacer layer, for example a dielectric such as silica, covering the metal layer and allowing contact between the quantum dot and the metal layer to be prevented. This spacer layer is for example a quarter-wave layer.

Simulations via calculation of finite differences in the time domain were carried out at the telecom wavelength of λ=1.55 μm. They relate to a source (i) not corresponding to the invention in that it does not have a structure having an index gradient (cf. FIG. 4a), a source (ii) according to the invention not having a reflective structure (cf. FIG. 4b), and another source (iii) according to the invention having a reflective structure such as a Bragg mirror (cf. FIG. 4c).

For these three sources, the cavity resulting from the etching has a maximum depth (height of the pyramid) of 10 μm. In the sources (ii) and (iii), the structure having an index gradient has a period of P1=0.15 μm and the filling factor f of silica in the amorphous silicon-silica bilayers varies from 20% to 80%. In the source (iii), the Bragg mirror comprises three bilayers with w1=0.26 μm and w2=0.11 μm.

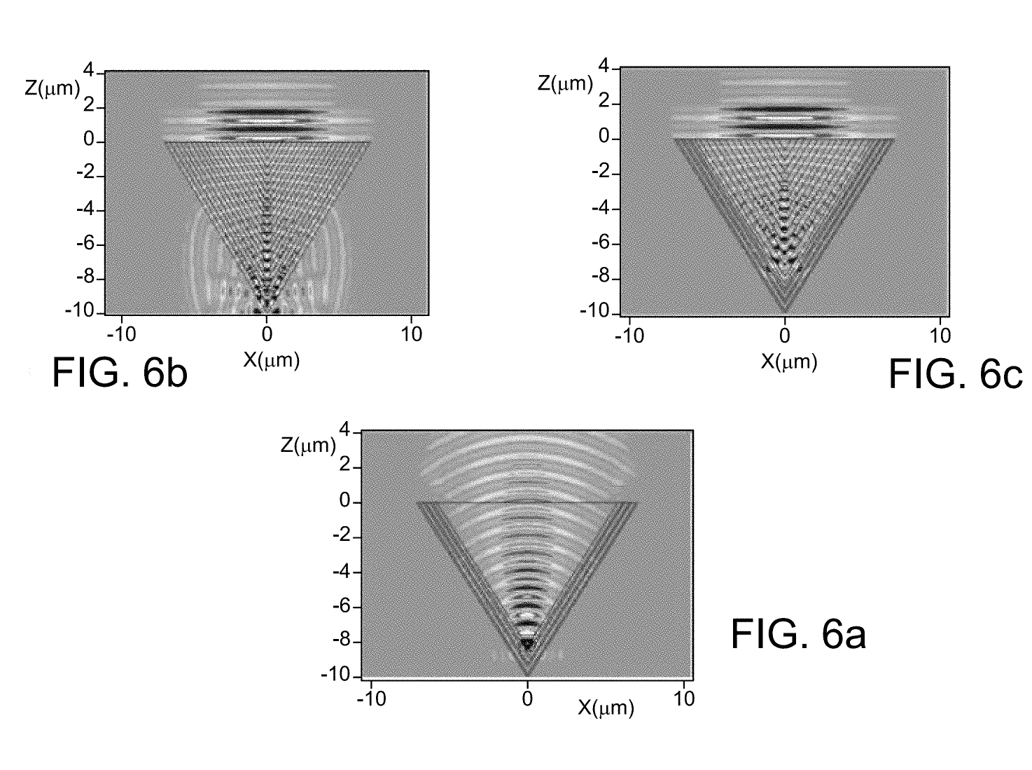

The simulation of the source (i) is shown in FIG. 6a. Isotropic emission is observed, with a non-collimated spherical wavefront. The simulations of the sources (ii) and (iii) are shown in FIGS. 6b and 6c, respectively. It is observed that the light is indeed collimated with a wavefront flattened by the structure having an index gradient. Moreover, a comparison of these figures shows that the Bragg mirror allows an emission entirely directed upwards to be obtained.

The invention is also of interest due to the fact that a scale factor can be applied to the pyramid, with the light still remaining collimated. Indeed, even if the size of the pyramid, that is to say X, is reduced, as long as the index relationship (2) indicated above is verified, the invention functions homothetically, the relationship (3) not being dependent on X. The invention can thus be applied to any pyramid size, and thus provide any desired directivity, since the wider the emission beam, the better the angular directivity.

FIGS. 1a-1e, 2a-2h and 3a-3e show three possible embodiments of a method for manufacturing a source according to the invention.

The first embodiment involves the etching of the substrate S in order to form a cavity therein resulting from the etching C (FIG. 1a). Then, the optional deposition of the Bragg mirror 3 on the sides of the cavity C resulting from etching is carried out, thus forming a pyramidal cavity C′ with reflective sides (FIG. 1b). Then, a quantum dot Bq is positioned at the apex 2′ of the pyramidal cavity (FIG. 1c). The various levels of the structure 4 having an index gradient are then deposited (FIG. 1d). Finally, chemical-mechanical planarisation CMP (“Chemical Mechanical Polishing”) or etching is carried out in order to planarise until the front face Sa of the substrate is reached (FIG. 1e).

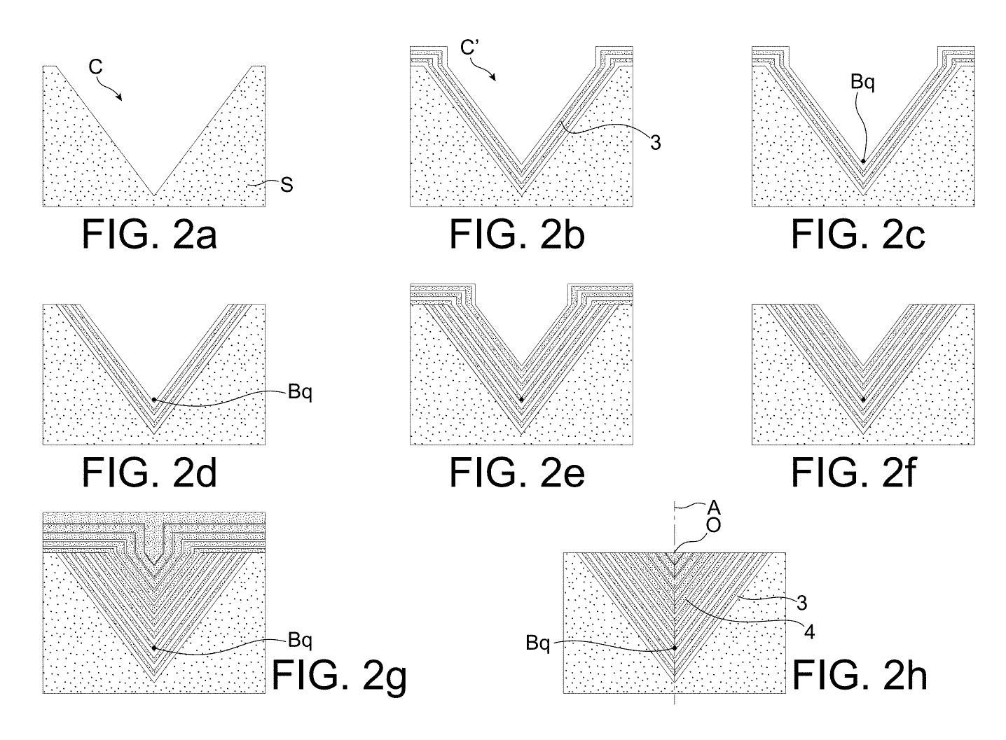

The three first steps of the second embodiment (FIGS. 2a-2c) are identical to those of the first embodiment. This second embodiment differs from the first in that a plurality of intermediate etchings or CMPs are carried out. Thus, in reference to FIG. 2d, etching or CMP is carried out until the front face of the substrate is reached. Then, a portion of the structure 4 having an index gradient is deposited (FIG. 2e). A new etching or CMP is carried out (FIG. 2f), before the end of the structure 4 having an index gradient is deposited (FIG. 2g) and a final etching or planarisation is carried out (FIG. 2h).

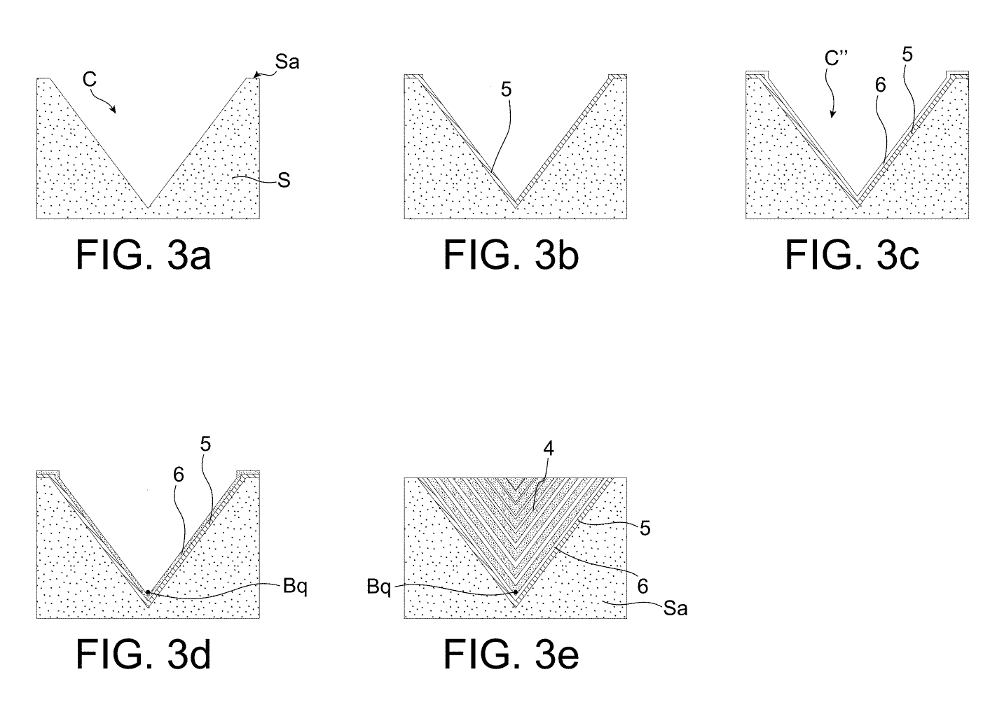

The third embodiment involves the etching of the substrate S in order to form a cavity resulting from etching C (FIG. 3a) therein. Then, a metal mirror 5 (FIG. 3b) is deposited, and said mirror is covered with a spacer layer (FIG. 3c) in order to form a pyramidal cavity C″ with reflective sides. Then, the quantum dot Bq is placed (FIG. 3d) and the structure 4 having an index gradient is formed (FIG. 3e).

The invention also relates to the use of the source as described above for the emission of a sequence of single photons.

The device can thus consist of a pulse pump laser and a pair of two APD (avalanche photodiode) fast detectors coupled with a pulse counter that measures the correlation function. The two detectors are each located on either side of a beam splitter receiving the flow of photons coming from the sample excited by the laser.

In an embodiment forming an alternative to the optical pumping, electric injection via the tunnel effect in the quantum dot can be carried out. For this purpose, the quantum dot is arranged in a dielectric layer sandwiched between two doped semiconductor layers, one n-type, the other p-type. The dielectric layer is for example an oxide such as silica, and the doped layers are for example layers of silicon. The thickness of the dielectric layer is several nanometres, adapted to the size of the quantum dot.

Since the doped layers are deposited on the whole wafer, they are found not only at the bottom of the pyramidal cavity, but also on the surface of the substrate, where metal contacts with these layers can be easily made using tracks or the metal tips. These electric contacts allow electric injection to be carried out, and the current cannot pass from one doped layer to another because of the dielectric layer, except via the quantum dot via the tunnel effect. By thus forcing the current to pass through the dot, good injection efficiency is provided, the injection of an electron-hole pair allowing the emission of a photon.

This electric injection is compatible with the presence of a reflective structure on the sides of the cavity. When this structure takes the form of a metal layer, the doped layer in contact with the metal layer acts as a spacer layer. This is preferably a quarter-wave layer. The metal layer can be used on the surface of the substrate to create electric contact, as an alternative to the doped layer in contact of the metal layer.

When the reflective structure is in the form of a Bragg layer, the last layer of the mirror (i.e. the upper layer) can be a semiconductor layer doped in such a way as to form one of the doped layers of the electric injection. This layer is a quarter-wave layer.

1. A source of collimated light, comprising:
a pyramidal cavity formed in a substrate having a front face, the pyramidal cavity having an axis of symmetry, a base at the front face of the substrate, a centre of the base, sides and an apex below the centre of the base along the axis of symmetry,
at least one quantum dot capable of emitting light with a wavefront, the at least one quantum dot being arranged at the apex of the pyramidal cavity, and
a structure having an index gradient that fills the pyramidal cavity, the effective index of which decreases from the centre of the base towards the sides in such a way as to flatten the wavefront of the light emitted by the at least one quantum dot.

2. The source of collimated light according to claim 1, wherein the structure having an index gradient has a continuous variation in refractive index from the centre of the base towards the sides.

3. The source of collimated light according to claim 1, wherein the structure having an index gradient is a stack of levels successively deposited in the pyramidal cavity conformally to the sides.

4. The source of collimated light according to claim 3, wherein the effective index of each level increases gradually from one level to another in the succession of the deposited levels.

5. The source of collimated light according to claim 3, wherein the levels have the same thickness.

6. The source of collimated light according to claim 5, wherein each level comprises a first layer and a second layer made from different materials, the relative thickness of the first and second layers of a level varying gradually from one level to another in the succession of the deposited levels.

7. The source of collimated light according to claim 6, wherein in each level, the material of the first layer has a refractive index lower than the refractive index of the material of the second layer, and wherein a factor of filling of a level by the first layer decreases from one level to another in the succession of the deposited levels.

8. The source of collimated light according to claim 7, wherein the material of the first layer is silica and the material of the second layer is amorphous silicon.

9. The source of collimated light according to claim 1, comprising a single quantum dot.

10. The source of collimated light according to claim 1, wherein the quantum dot is arranged in a dielectric layer sandwiched between two doped semiconductor layers, one n-type, the other p-type.

11. The source of collimated light according to claim 1, further comprising a reflective structure on the sides of the pyramidal cavity, for example a Bragg mirror or a metal layer.

12. A method for emitting a sequence of single photons comprising the step of operating the source of collimated light according to claim 9.

13. A method for manufacturing a source of collimated light, comprising the following of:
forming a pyramidal cavity in a substrate having a front face, the pyramidal cavity having an axis of symmetry, a base at the front face of the substrate, a centre of the base, sides and an apex below the centre of the base along the axis of symmetry,
arranging, at the apex of the pyramidal cavity, of at least one quantum dot suitable for emitting light with a wavefront, and
filling the pyramidal cavity with a structure having an index gradient, the effective index of which decreases from the centre of the base towards the sides.

14. The method according to claim 13, wherein the step of arranging the at least one quantum dot at the apex of the pyramidal cavity comprises depositing a colloidal solution of quantum dots on the substrate.

15. The method according to claim 13, wherein the step of arranging the at least one quantum dot at the apex of the pyramidal cavity is preceded by a step of forming a reflective structure on the sides of the pyramidal cavity.
